(19) United States
(12) Patent Application Publication
(10) Pub. No.: US 2012/0048375 A1
(43) Pub. Date: Mar. 1, 2012

(54) FILM USED FOR SOLAR CELL MODULE AND MODULE THEREOF

(76) Inventors: TSUN-MIN HSU, Kaohsiung (TW); Yu-Ming Sun, Kaohsiung (TW); Chung-Hua Yang, Kaohsiung (TW); Jui-Kai Hu, Kaohsiung (TW)

(21) Appl. No.: 13/291,810

(22) Filed: Nov. 8, 2011

(30) Foreign Application Priority Data
Aug. 11, 2010 (TW) 099138379

(51) Int. Cl. H01L 31/0232; G02B 5/02; H01L 31/0203

(52) U.S. Cl. 136/259; 359/599

(57) ABSTRACT

The present invention is directed to a film used for a solar cell module and the module thereof, in which the film includes a substrate and at least one light-regulating layer, and the light-regulating layer includes a fluoro resin and a plurality of light diffusing additives. By applying the film of the subject invention in a solar cell module, the film can make the solar cell have good light utilization.

### BACKGROUND OF THE INVENTION

1. Field of the Invention

The present invention relates to a light-regulating film, and more particularly to a film used for a solar cell module.

2. Description of the Prior Art

Since such environmental protection problems as energy source shortage and greenhouse effect are increasingly serious, currently, countries are actively researching and developing various possible sustainable energy sources, and particularly, industries attach the most importance to solar power generation. As shown in FIG. 1, generally, a solar cell module is sequentially formed of a transparent frontsheet 11 (generally, a glass sheet), an encapsulant layer, a solar cell unit 12, an encapsulant layer, and a backsheet 13.

In order to reduce the cost of the solar power generation, currently, a common approach in the industry is to increase the power generation conversion efficiency of sunlight. However, when incident light 14 of the sun enters the solar cell module from air 16, is reflected in the module, and then reaches an interface between the transparent frontsheet and the air, if the face angle of reflected light 15 is smaller than a particular critical angle a for total internal reflection, the reflected light 15 would directly penetrate the module and cannot be absorbed and utilized again by a solar cell, and the increase of the conversion efficiency of the sunlight is also limited accordingly. Therefore, currently, the industry urgently needs to seek a technical solution for solving the foregoing problem, to achieve full utilization of the sunlight in the solar cell module.

### SUMMARY OF THE INVENTION

Accordingly, the present invention is mainly directed to a film for increasing sunlight utilization and a module thereof.

In order to achieve the foregoing and other objectives, the present invention provides a film used for a solar cell module, and the film comprises: a substrate and at least one light-regulating layer, wherein the light-regulating layer comprises a fluoro resin and a plurality of light diffusing additives.

The present invention further provides a solar cell module including the foregoing film, and the solar cell module comprises: a transparent frontsheet; a backsheet; and one or more solar cells located between the transparent frontsheet and the backsheet, in which at least one of the transparent frontsheet and the backsheet includes the foregoing film.

### BRIEF DESCRIPTION OF THE DRAWINGS

FIG. 1 is a simple schematic view of a solar cell module of the prior art.

FIG. 2 illustrates curves of light intensity distribution corresponding to reflection of angles measured at an incident angle of 0°.

FIG. 3 illustrates an embodiment of the film according to the present invention.

FIG. 4 illustrates an embodiment of the film according to the present invention.

FIG. 5 illustrates an embodiment of the solar cell module according to the present invention.

FIG. 6 illustrates an embodiment of the solar cell module according to the present invention.

FIG. 7 illustrates an embodiment of the solar cell module according to the present invention.

FIG. 8 illustrates an embodiment of the solar cell module according to the present invention.

FIG. 9 illustrates an embodiment of the solar cell module according to the present invention.

FIG. 10 illustrates an embodiment of the solar cell module according to the present invention.

FIG. 11 illustrates an embodiment of the solar cell module according to the present invention.

FIG. 12 illustrates an embodiment of the solar cell module according to the present invention.

FIGS. 13A and 13B are schematic structural views of a solar cell module according to the present invention, in which FIG. 13A is a top view, and FIG. 13B is a side view taken along the dashed line in FIG. 13A.

FIG. 14 illustrates the influence of the content of light diffusing additives on the power generation efficiency of the solar cell module when the film of the present invention is disposed on a backsheet (with a light-regulating layer facing upward).

FIG. 15 illustrates the influence of the content of the light diffusing additives on the power generation efficiency of the solar cell module when the film of the present invention is disposed on a backsheet (with a light-regulating layer facing downward).

FIG. 16 illustrates the comparison of the power generation efficiency of the solar cell module with a film according to the present invention on a backsheet that contains a single light-regulating layer (with the light-regulating layer facing downward) with that of the solar cell module with a film according to the present invention on a backsheet that contains two light-regulating layers.

FIG. 17 illustrates the comparison of the efficiency of the solar cell module with a film according to the present invention that is disposed on a frontsheet with that of the solar cell module with a film according to the present invention that is disposed on a backsheet.

### DETAILED DESCRIPTION OF THE INVENTION

When light enters a solar cell module, passes through a transparent frontsheet, and reaches a solar cell and a backsheet, due to reflection or scattering, the incident light turns into reflected light. Before the reflected light returns to the transparent frontsheet and again enters the air, at the interface between the transparent frontsheet and the air, there exists two possible circumstances, that is, the reflected light is returned into the cell module through total internal reflection or enters the air through refraction. If the face angle of the reflected light is larger than a particular critical angle a (if the transparent frontsheet is a glass sheet, the included angle relative to the normal of the surface of about 42 degrees), total internal reflection of the light happens, and the reflected light returns into the solar cell module and is effectively utilized once more. According to Snell's Law, when the incident light (that is, the reflected light) enters from a medium of a refractive index n₁ to another medium of a refractive index n₂, and refracted light is generated, the correlation between the incident light and the refracted light is as follows: n₁ sin θ₁=n₂ sin θ₂, where θ₁ is an included angle between the incident light and the normal, and θ₂ is an included angle between the refracted light and the normal.

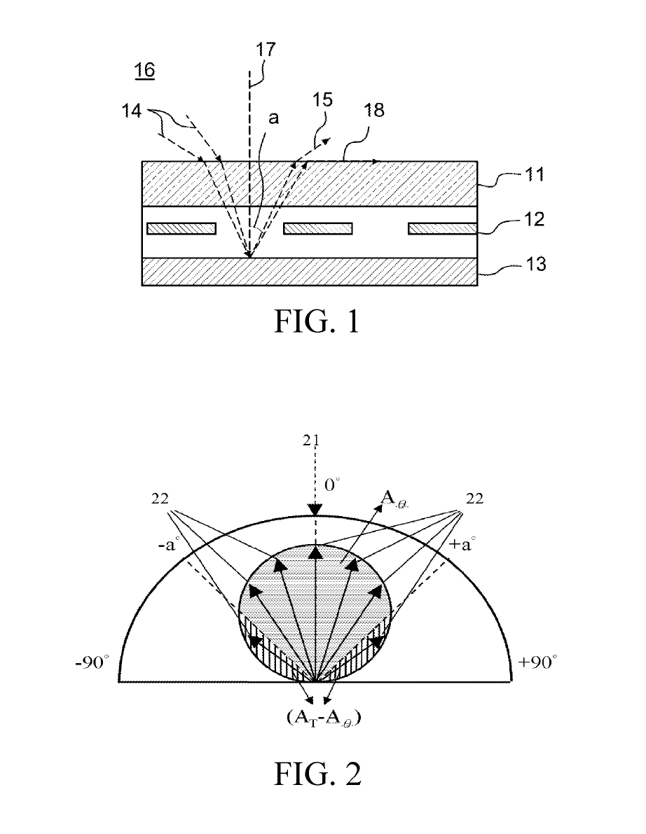

As shown in FIG. 1, when the medium of the refractive index n₂ is the air 16 (n₂=1), if the refracted light is required to generate totally reflected light 18, θ₂ needs to be larger than or equal to 90°. In a case of the minimal angle at which the refracted light generates total reflection)(θ₂=90°, the minimal incident critical angle corresponding to the incident light is θ₁=a, and all incident angles larger than the critical angle a enable the corresponding refracted light to generate total internal reflection.

As shown in FIG. 2, “the reflected light of total internal reflection (TIR)” (A_{T}-A_{θ}) herein refers to the amount of all the reflected light that cause total internal reflection when the sunlight enters the solar cell module of the present invention, is reflected from the solar cell and the backsheet, then returns to the transparent frontsheet and enters the air, where A_{T} is the total amount of the reflected light, A_{θ} is the amount of the reflected light that does not cause total internal reflection, and θ satisfies the following formula:

−a<θ<a, and a=sin⁻¹(1/n₁),

where n₁ is the refractive index of the material of the contact surface (the incident surface of the sunlight) between the transparent frontsheet and the air.

When the transparent frontsheet is glass (n₁=1.51), a is about 42°.

Herein, a parameter of TIR ratio is defined as “a ratio of the amount (A_{T}−A_{θ}) of the reflected light that cause TIR of a film used for the solar cell module to the total amount (A_{T}) of the reflected light,” which refers to a percentage of the foregoing reflected light that cause TIR to all the reflected light, that is, satisfies the following formula:

TIR ratio=[(A_{T}−A_{θ})/A_{T}]×100%.

When the TIR ratio of the film used for the solar cell module according to the present invention is larger than 10%, the power generation efficiency of the solar cell module can be apparently improved.

The film of the present invention may be transparent, translucent or opaque as required. The surface of a light-regulating layer of the film in the present invention may have a smooth structure or a concave-convex structure, and is preferably a surface having a concave-convex structure.

The shape of the light diffusing additives included in the light-regulating layer of the film of the present invention is not specially limited, and may be, for example, spherical, rhombus-shaped, elliptical, rice grain-shaped, polygonal spherical or biconvex-shaped, among which the spherical shape is preferred. The structure of the foregoing light diffusing additives may be, for example, a solid structure, a hollow structure, a porous structure or a combination thereof.

The material of the foregoing light diffusing additives may be, for example, glass, a metal oxide or plastic. The metal oxide may be, for example but is not limited to, TiO₂, SiO₂, ZnO, Al₂O₃, ZrO₂ or a mixture thereof. The plastic may be, for example but is not limited to, an acrylate resin, a styrene resin, a urethane resin, a silicone resin or a mixture thereof. According to a preferred embodiment of the present invention, the material of the light diffusing additives is an acrylate resin, a silicone resin or a combination thereof.

The average particle size of the foregoing light diffusing additives is about 0.5 μm to 10 μm, preferably about 1 μm to 5 μm.

The content of the light diffusing additives is 5 wt % to 80 wt %, preferably 10 wt % to 60 wt % based on the total weight of the light-regulating layer.

The fluoro resin included in the light-regulating layer of the film used for the solar cell module according to the present invention comprises a copolymer of a fluoroolefin monomer and an alkyl vinyl ether monomer.

According to the present invention, the fluoroolefin monomer which may be used for forming the fluoro resin is well known to persons skilled in the art, which is, for example but not limited to, vinyl fluoride, vinylidene fluoride, trifluorochloroethylene, tetrafluoroethylene, hexafluoropropylene or a mixture thereof, and preferably trifluorochloroethylene.

According to the present invention, the alkyl vinyl ether monomer which may be used for forming the fluoro resin is not specially limited, and may be one selected from the group consisting of a straight chain alkyl vinyl ether monomer, a side chain alkyl vinyl ether monomer, a cyclic alkyl vinyl ether monomer, and a hydroxyl alkyl vinyl ether monomer, and a mixture thereof.

Preferably, the alkyl in the alkyl vinyl ether has a carbon number of C₂ to C₁₁.

The fluoro resin used as a binder in the present invention provides an advantage of good weather resistance, and the content of the fluoro resin is 20 wt % to 95 wt %, preferably 40 wt % to 90 wt % based on the total weight of the light-regulating layer.

Optionally, a curing agent can be added to the light-regulating layer of the film used for the solar cell module according to the present invention, which plays the role of generating a chemical bond between molecules with the binder, so as to form crosslinking. The curing agent used in the present invention is well known to persons skilled in the art, and can be, for example, polyisocyanate.

The content of the foregoing curing agent is 0 wt % to 20 wt %, preferably 5 wt % to 10 wt % based on the total weight of the light-regulating layer.

Optionally, inorganic particles can be added to the light-regulating layer of the film used for the solar cell module, and the species of the inorganic particles may be, for example but is not limited to, aluminum nitride, magnesium oxide, silicon nitride, boron nitride, zinc oxide, silicon dioxide, titanium dioxide, zirconium oxide, iron oxide, aluminum oxide, calcium sulfate, barium sulphate or calcium carbonate or a mixture thereof, among which titanium dioxide is preferred.

The inorganic particles used in the light-regulating layer of the film used for the solar cell module of the present invention are used for color adjustment and for improving the reflection of the backsheet, and may also enable the backsheet to have an excellent ultraviolet absorption property. The inorganic particles optionally added to the light-regulating layer of the film used for the solar cell module of the present invention generally have a particle size of 0.01 μm to 20 μm, preferably 1 μm to 10 μm. The content of the inorganic particles used in the film of the present invention is 0 wt % to 75 wt %, preferably 1 wt % to 40 wt % based on the total weight of the light-regulating layer.

Optionally, conventional additives known to persons skilled in the art can be added to the light-regulating layer of the film used for the solar cell module according to the present invention.

The light-regulating layer of the film used for the solar cell module according to the present invention may be formed by, for example, but not limited to, knife coating, roller coating, micro gravure coating, flow coating, dip coating, spray coating, or curtain coating. According to an embodiment of the invention, the application method is roller coating.

The material of the substrate of the film used for the solar cell module according to the present invention may be, for example, glass, metal or resin. The resins useful for the present invention may include, but are not limited to, a polyester resin, such as polyethylene terephthalate (PET) or polyethylene naphthalate (PEN); a polyacrylate resin, such as polymethyl methacrylate (PMMA); a polyolefin resin, such as polyethylene (PE) or polypropylene (PP); a polycycloolefin resin; a polyimide resin; a polycarbonate resin; a polyurethane resin; polyvinyl chloride (PVC); triacetyl cellulose (TAC); or a polylactic acid, or a combination thereof, of which the polyester resin, polycarbonate resin, or a combination thereof is preferred and PET is more preferred.

According to an embodiment of the present invention, the transparent frontsheet in the solar cell module may be the film of the present invention, the backsheet in the solar cell module of the present invention may also be the film of the present invention, or both the transparent frontsheet and the backsheet are respectively the films. According to the present invention, a single surface of the substrate of the film has the light-regulating layer, or two surfaces of the substrate of the film respectively have the light-regulating layers. When the film is the transparent frontsheet, the substrate of the light-regulating film is a transparent substrate.

The construction of the film used for the solar cell module according to the present invention and the module thereof is exemplified hereinafter with reference to the drawings, which is not intended to limit the scope of the present invention. Modifications and changes which may be easily achieved by persons of ordinary skill in the art are included in the disclosure of the specification.

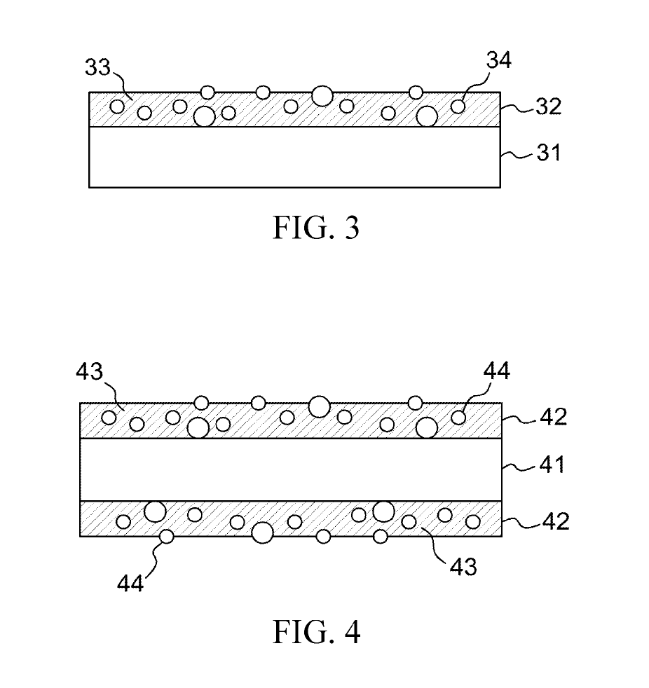

FIG. 3 illustrates a preferred embodiment of a film used for a solar cell module of the present invention. The film used for the solar cell module includes a substrate 31 and a light-regulating layer 32. The light-regulating layer 32 includes a fluoro resin 33 and a plurality of light diffusing additives 34.

FIG. 4 illustrates another preferred embodiment of a film used for a solar cell module of the present invention. The film used for the solar cell module forms a light-regulating layer 42 at two sides of a substrate 41 respectively.

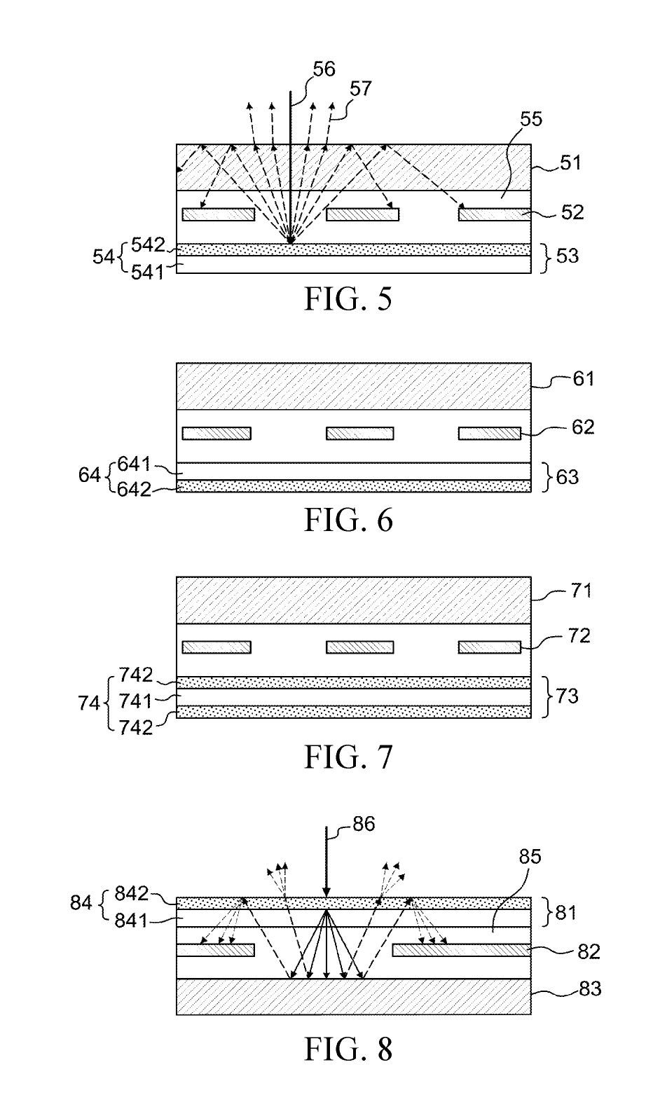

FIG. 5 illustrates an embodiment of a solar cell module according to the present invention. The solar cell module includes a transparent frontsheet 51, a plurality of solar cells 52, and a backsheet 53. The transparent frontsheet of this embodiment is a transparent glass substrate or other transparent plastic substrate. Suitable resins for the transparent plastic substrate include, but are not limited to, a polyester resin, such as polyethylene terephthalate (PET) or polyethylene naphthalate (PEN); a polyacrylate resin, such as polymethyl methacrylate (PMMA); a polyolefin resin, such as polyethylene (PE) or polypropylene (PP); a polycycloolefin resin; a polyimide resin; a polycarbonate resin; a polyurethane resin; polyvinyl chloride (PVC); triacetyl cellulose (TAC); polylactic acid; or a combination thereof. Preferably, the transparent frontsheet is formed from a polyacrylate resin, polycarbonate resin, or a combination thereof. The backsheet is a film 54 as described above, in which the plurality of solar cells 52 is located between the transparent frontsheet and the backsheet, and the type of the solar cell may be, for example but is not limited to, a monocrystalline silicon solar cell, a poly-silicon solar cell, an amorphous silicon solar cell, a dye-sensitized solar cell, an inorganic compound semiconductor cell, or an organic solar cell. The type of the inorganic compound semiconductor cell may be, for example but is not limited to, a III-V group compound semiconductor cell, such as GaAs, GaN, InP, or InGaP; a II-VI group compound semiconductor cell, such as CdS or CdTe; a I-III-VI group compound semiconductor cell, such as CuInSe or CIGS; or a CZTS compound semiconductor cell. The embodiment shown in FIG. 5 is a monocrystalline silicon solar cell, and the present invention may select different packaging materials according to the different types of the solar cell. According to a preferred embodiment of the present invention, when the solar cell is the monocrystalline silicon solar cell, the selected encapsulant material 55 is ethylene vinyl acetate (EVA). The film 54 includes a substrate 541 and at least one light-regulating layer 542. According to an embodiment of the present invention, a light-regulating layer 542 is provided on the substrate, in which the light-regulating layer includes a fluoro resin and a plurality of light diffusing additives.

The foregoing film is located in the backsheet, and the light scattering phenomenon occurring when the sunlight 56 is incident to the film 54 may increase the quantity of the reflected light of the TIR and raise the utilization of the sunlight, so as to improve the photoelectric conversion efficiency.

FIG. 6 illustrates another embodiment of the present invention, in which a light-regulating layer 642 is located below a substrate 641.

FIG. 7 illustrates yet another embodiment of the present invention, in which both upper and lower sides of a substrate 741 are provided with a light-regulating layer 742.

FIG. 8 illustrates yet another embodiment of the present invention, and a solar cell module in FIG. 8 includes a transparent frontsheet 81, a plurality of solar cells 82, and a backsheet 83. A transparent frontsheet of this embodiment is a film 84, the film 84 includes a substrate 841 and a light-regulating layer 842, and the light-regulating layer 842 is located on the substrate, in which the light-regulating layer includes a fluoro resin and a plurality of light diffusing additives.

The foregoing film is located in the frontsheet, and the light scattering phenomenon occurring when the sunlight 86 is incident to the film 84 may increase the reflected light of the TIR of the solar cell module and raise the utilization of the sunlight, so as to improve the photoelectric conversion efficiency of the solar cell module.

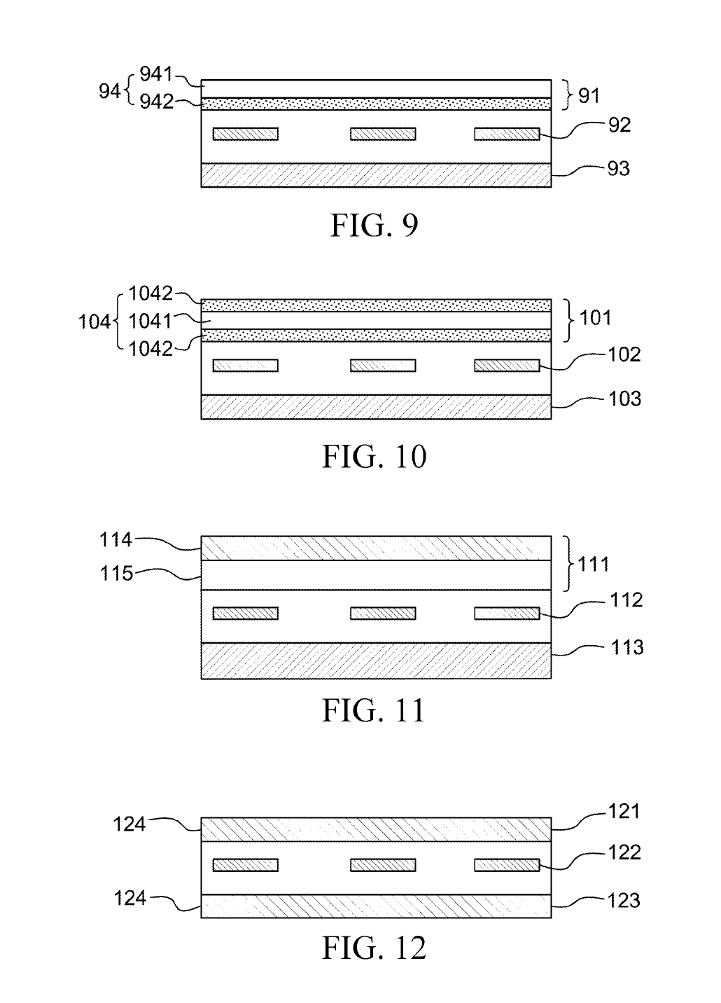

FIG. 9 illustrates yet another embodiment of the present invention, in which a light-regulating layer 942 is located below a substrate 941 of a transparent frontsheet.

FIG. 10 illustrates yet another embodiment of the present invention, in which both upper and lower sides of a substrate 1041 of a transparent frontsheet are provided with a light-regulating layer 1042.

According to another embodiment of the present invention, as shown in FIG. 11, a transparent frontsheet 111 sequentially includes a film 114 and a glass substrate or other transparent substrate 115 from top to bottom.

FIG. 12 illustrates yet another embodiment of the present invention, in which a transparent frontsheet 121 of a solar cell module of the present invention is a film 124, and a backsheet 123 is another film 124.

### EXAMPLES

The following examples are provided to further illustrate the present invention, and not intended to limit the scope of the present invention. Modifications and variations achieved by persons skilled in the art without departing from the spirit of the present invention shall fall within the scope of the present invention.

### Working Examples

### Preparation for a Solar Cell Module

### Preparation Example 1

A Tedlar/PET/Tedlar (TPT) lamination structure was manufactured by placing polyethylene terephthalate (PET) (O321E188, Mitsubishi Company) with the thickness of 188 μm between two polyvinyl fluoride layers (with the thickness of 25 μm, Tedlar® PV2001, DuPont Company), and then performing a vacuum hot-pressing procedure.

### Preparation Example 2

79.64 grams of a fluoro resin (Eterflon 4101-50 provided by Eternal Company, having a solids content of 50%, and being a trifluorochloroethylene and alkyl vinyl ether copolymer resin) was taken and added to a plastic bottle, then 6.79 grams of a solvent (butyl acetate) was added under high speed stirring, then 13.57 grams of a curing agent (Desmodur 3390 provided by Bayer Company, having a solids content of about 75%, and being an isocyanate curing agent) was added, and a coating with a solids content of about 50% and a total weight of about 100 grams was formulated. With an RDS coating rod #35, the coating was applied onto one side of a PET (O321E188, Mitsubishi Company) substrate, and a coating layer (light-regulating layer) with the film thickness of about 25 μm was obtained after drying for 2 minutes at 120° C.

### Preparation Example 3

30.72 grams of a fluoro resin (Eterflon 4101-50 provided by Eternal Company, having a solids content of 50%, and being a trifluorochloroethylene and alkyl vinyl ether copolymer resin) was taken and added in a plastic bottle, then 33.33 grams of a solvent (butyl acetate) and 30.72 grams of light diffusing additives (Tospearl 120E provided by GE Toshiba Silicones Company, being silicone resin solid spherical particulates with an average particle size of 2 μm) were sequentially added under high speed stirring, and finally 5.23 grams of a curing agent (Desmodur 3390 provided by Bayer Company, having a solids content of about 75%, and being an isocyanate curing agent) was added, so that a coating with the solids content of about 50% and the total weight of about 100 grams was formulated. With an RDS coating rod #35, the coating was applied onto one side of a PET (O321E188, Mitsubishi Company) substrate, and a coating layer (light-regulating layer) with the film thickness of about 25 μm was obtained after drying for 2 minutes at 120° C.

### Preparation Example 4

The steps in Preparation Example 3 were repeated, except that the amounts of the fluoro resin, the solvent, the light diffusing additives, and the curing agent were changed to 23.5 grams, 37.25 grams, 35.25 grams, and 4 grams, respectively.

### Preparation Example 5

44.33 grams of a fluoro resin (Eterflon 4101-50 provided by Eternal Company, having a solids content of 50%, and being a trifluorochloroethylene and alkyl vinyl ether copolymer resin) was taken and added in a plastic bottle, then 25.94 grams of a solvent (butyl acetate) and 22.17 grams of an inorganic particle TiO₂ (R-902 provided by DuPont Company) were sequentially added under high speed stirring, and finally 7.56 grams of a curing agent (Desmodur 3390 provided by Bayer Company, having a solids content of about 75%, and being an isocyanate curing agent) was added, so that a coating with the solids content of about 50% and the total weight of about 100 grams was formulated. With an RDS coating rod #35, the coating was applied onto one side of a PET (O321E188, Mitsubishi Company) substrate, and a coating layer (light-regulating layer) with the film thickness of about 25 μm was obtained after drying for 2 minutes at 120° C.

### Preparation Example 6

44.33 grams of a fluoro resin (Eterflon 4101-50 provided by Eternal Company, having a solids content of 50%, and being a trifluorochloroethylene and alkyl vinyl ether copolymer resin) was taken and added in a plastic bottle, then 25.94 grams of a solvent (butyl acetate), 17.73 grams of an inorganic particle TiO₂ (R-902 provided by DuPont Company), and 4.43 grams of light diffusing additives (Tospearl 120E provided by GE Toshiba Silicones Company, being silicone resin solid spherical particulates with the average particle size of 2 μm) were sequentially added under high speed stirring, and finally 7.56 grams of a curing agent (Desmodur 3390 provided by Bayer Company, having a solids content of about 75%, and being an isocyanate curing agent) was added, so that a coating with the solids content of about 50% and the total weight of about 100 grams was formulated. With an RDS coating rod #35, the coating was applied onto one side of a PET (O321E188, Mitsubishi Company) substrate, and a coating layer (light-regulating layer) with the film thickness of about 25 μm was obtained after drying for 2 minutes at 120° C.

### Preparation Example 7

The steps in Preparation Example 6 were repeated, except changing both the added quantities of TiO₂ and the light diffusing additives to 11.08 grams.

### Preparation Example 8

The steps in Preparation Example 5 were repeated, except that the added quantities of the fluoro resin, the solvent, TiO₂, and the curing agent were changed to 30.72 grams, 33.33 grams, 30.72 grams, and 5.24 grams respectively.

### Preparation Example 9

The steps in Preparation Example 6 were repeated, except that the added quantities of the fluoro resin, the solvent, TiO₂, the light diffusing additives, and the curing agent were changed to 30.72 grams, 33.33 grams, 23.04 grams, 7.68 grams, and 5.24 grams respectively.

### Preparation Example 10

The steps in Preparation Example 9 were repeated, except that both the added quantities of TiO₂ and the light diffusing additives were changed to 15.36 grams.

### Preparation Example 11

The steps in Preparation Example 9 were repeated, except that the added quantities of TiO₂ and the light diffusing additives were changed to 7.68 grams and 23.04 grams respectively.

### Preparation Example 12

The steps in Preparation Example 5 were repeated, except that the added quantities of the fluoro resin, the solvent, TiO₂, and the curing agent were changed to 23.5 grams, 37.25 grams, 35.25 grams, and 4.01 grams respectively.

### Preparation Example 13

The steps in Preparation Example 6 were repeated, except that the added quantities of the fluoro resin, the solvent, TiO₂, the light diffusing additives, and the curing agent were changed to 23.5 grams, 37.25 grams, 29.37 grams, 5.88 grams, and 4.00 grams respectively.

### Preparation Example 14

The steps in Preparation Example 13 were repeated, except that the added quantities of TiO₂ and the light diffusing additives were changed to 23.5 grams and 11.75 grams respectively.

### Preparation Example 15

The steps in Preparation Example 13 were repeated, except that both the added quantities of TiO₂ and the light diffusing additives were changed to 17.62 grams.

### Preparation Example 16

The steps in Preparation Example 13 were repeated, except that the added quantities of TiO₂ and the light diffusing additives were changed to 11.75 grams and 23.5 grams respectively.

### Preparation Example 17

The steps in Preparation Example 13 were repeated, except that the added quantities of TiO₂ and the light diffusing additives were changed to 5.87 grams and 29.37 grams respectively.

### Bilayered Film Preparation

### Preparation Example 18

A coating of the same formula as that in Preparation Example 3 was applied onto the uncoated side of the substrate of Preparation Example 3, a coating layer (light-regulating layer) with the film thickness of about 25 μm was obtained after drying for 2 minutes at 120° C., and a film coated on double sides was formed.

### Preparation Example 19

A coating of the same formula as that in Preparation Example 7 was applied onto the uncoated side of the substrate in Preparation Example 7, a coating layer (light-regulating layer) with the film thickness of about 25 μm was obtained after drying for 2 minutes at 120° C., and a film with coated on double sides was formed.

### Preparation Example 20

A coating of the same formula as that in Preparation Example 11 was applied onto the uncoated side of the substrate in Preparation Example 11, a coating layer (light-regulating layer) with the film thickness of about 25 μm was obtained after drying for 2 minutes at 120° C., and a film coated on double sides was formed.

### Preparation Example 21

A coating of the same formula as that in Preparation Example 17 was applied onto the uncoated side of the substrate in Preparation Example 17, a coating layer (light-regulating layer) with the film thickness of about 25 μm was obtained after drying for 2 minutes at 120° C., and a film coated on double sides was formed.

### Preparation Example 22

The steps in Preparation Example 3 were repeated, except that the added quantities of the fluoro resin, the solvent, the light diffusing additives, and the curing agent were changed to 32.73 grams, 32.24 grams, 29.45 grams, and 5.58 grams respectively.

### Manufacture of Solar Cell Module with Film of the Present Invention at the Backsheet

### Example 1A

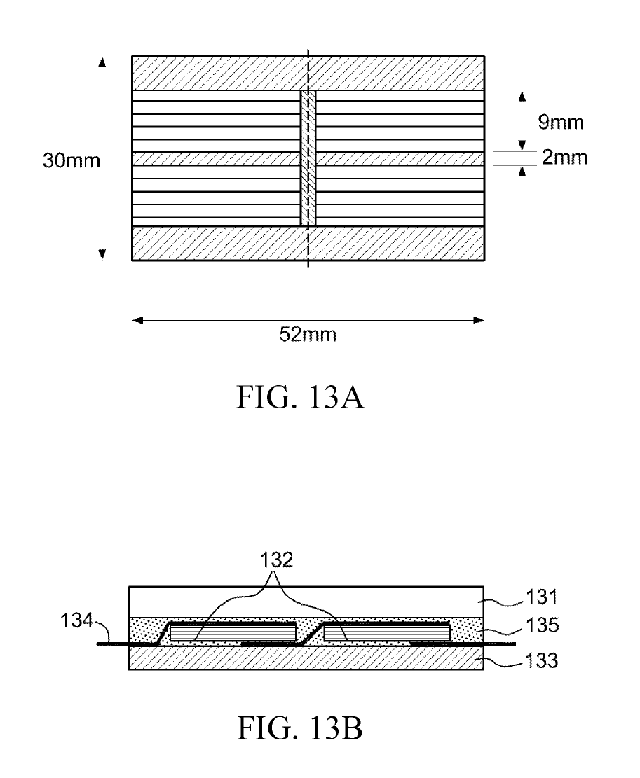

As shown in FIGS. 13A and 13B, tempered glass (protection glass, provided by Asahi Glass Company), an encapsulant material EVA resin (SOLAR EVA, provided by Mitsui Fabro Company), a monocrystalline silicon solar cell unit (GIN156S, provided by GINTECH Company, in which the cell unit is formed by performing series welding on two silicon chips with the dimension of 52 mm×9 mm in a manner of making longer sides parallel to each other, and the silicon chips were separated from each other by 2 mm), and a backsheet as described in Preparation Example 3 (with the coating layer facing upward) were sequentially overlapped, and were laminated by using a vacuum laminating machine, so as to obtain a solar cell module.

### Examples 2A to 12A

The steps in Example 1A were repeated, except replacing Preparation Example 3 with Preparation Example 4, Preparation Example 6, Preparation Example 7, Preparation Example 9, Preparation Example 10, Preparation Example 11, Preparation Example 13, Preparation Example 14, Preparation Example 15, Preparation Example 16, and Preparation Example 17, respectively.

### Example 1B

The steps in Example 1A were repeated, except that the backsheet was placed with the coating layer facing downward.

### Examples 2B to 12B

The steps in Example 1B were repeated, except replacing Preparation Example 3 with Preparation Example 4, Preparation Example 6, Preparation Example 7, Preparation Example 9, Preparation Example 10, Preparation Example 11, Preparation Example 13, Preparation Example 14, Preparation Example 15, Preparation Example 16, and Preparation Example 17, respectively.

### Examples 13 to 16

The steps in Example 1A were repeated, except replacing Preparation Example 3 with Preparation Examples 18 to 21, respectively.

### Manufacture of Solar Cell Module with the Films of the Present Invention at the Frontsheet and the Backsheet

### Example 17A

Preparation Example 22 (with the coating surface facing upward) was attached to an upper surface of the tempered glass in Example 12A, so as to obtain the solar cell module.

### Example 17B

Preparation Example 22 (with the coating surface facing downward) was attached to an upper surface of the tempered glass in Example 12A, so as to obtain the solar cell module.

### Comparative Examples

### Comparative Example 1

The steps in Example 1A were repeated, except changing Preparation Example 3 to Preparation Example 1.

### Comparative Example 2A

The steps in Example 1A were repeated, except changing Preparation Example 3 to Preparation Example 2.

### Comparative Example 2B

The steps in Example 1B were repeated, except changing Preparation Example 3 to Preparation Example 2.

### Comparative Example 3A

The steps in Example 1A were repeated, except changing Preparation Example 3 to Preparation Example 5.

### Comparative Example 3B

The steps in Example 1B were repeated, except changing Preparation Example 3 to Preparation Example 5.

### Comparative Example 4A

The steps in Example 1A were repeated, except changing Preparation Example 3 to Preparation Example 8.

### Comparative Example 4B

The steps in Example 1B were repeated, except changing Preparation Example 3 into Preparation Example 8.

### Comparative Example 5A

The steps in Example 1A were repeated, except changing Preparation Example 3 to Preparation Example 12.

### Comparative Example 5B

The steps in Example 1B were repeated, except changing Preparation Example 3 to Preparation Example 12.

<Test Methods>

1. A ratio of the reflected light (A_{T}-A_{θ}) of the TIR to the total reflected light (A_{T}) of the film, that is, a TIR ratio, was obtained; as shown in FIG. 2, curves of light intensity distribution corresponding to reflection of angles were measured at an incident angle of 0° by using an automatic variable-angle photometer (GonioPhotometer, GP-200, provided by MURAKAMI Color Company), and then the areas surrounded by the curves were integrated respectively to obtain A_{T} and A_{θ}, which were introduced into the following formula:

TIR ratio=[(A_{T}−A_{θ})/A_{T}]×100%,

so that the TIR ratio was obtained, where θ is a critical angle for generating the TIR, −a<θ<a, a=sin⁻¹ (1/n₁), and n₁ is the refractive index of the material of the contact surface (the incident surface of the sunlight) between the transparent frontsheet and the air. Test results are as shown in Table 1, Table 2, and Table 3.

2. A test of the efficiency (η) of the solar cell module was performed, in which a solar simulator (Model: 92193A-1000, Newport Company) was used under the condition of AM1.5 luminance to irradiate the solar cell module to be tested, an I-V characteristic curve was measured, and then the efficiency (η=Pmax/Pin) of the solar cell module was calculated. Test results are as shown in Table 1, Table 2, and Table 3.

TABLE 1
Relationship between TIR and η of a backsheet having a single-sided coating layer

| | | | Coating layer facing upward | | | Coating layer facing downward | | |
|---|---|---|---|---|---|---|---|---|
| | | | | | Module | | | Module |
| | Coating | | | | power | | | power |
| | layer | | TIR | | generation | TIR | | generation |
| | formula | | ratio | | efficiency | ratio | | efficiency |
| Backsheet | T/R | B/R | (%) | Cell module | η (%) | (%) | Cell module | η (%) |
| Preparation | — | — | 16.14 | Comparative | 17.05 | — | — | — |
| Example 1 | | | | Example 1 | | | | |
| Preparation | 0 | 0 | 0 | Comparative | 16.84 | 0 | Comparative | 16.84 |
| Example 2 | | | | Example 2A | | | Example 2B | |
| Preparation | 0 | 2 | 40.52 | Example 1A | 17.24 | 37.89 | Example 1B | 17.22 |
| Example 3 | | | | | | | | |
| Preparation | 0 | 3 | 46.40 | Example 2A | 17.36 | 43.14 | Example 2B | 17.34 |
| Example 4 | | | | | | | | |
| Preparation | 1 | 0 | 10.81 | Comparative | 17.20 | 7.94 | Comparative | 17.16 |
| Example 5 | | | | Example 3A | | | Example 3B | |
| Preparation | 0.8 | 0.2 | 11.78 | Example 3A | 17.20 | 8.85 | Example 3B | 17.17 |
| Example 6 | | | | | | | | |
| Preparation | 0.5 | 0.5 | 13.21 | Example 4A | 17.22 | 10.31 | Example 4B | 17.18 |
| Example 7 | | | | | | | | |
| Preparation | 2 | 0 | 11.08 | Comparative | 17.20 | 9.08 | Comparative | 17.16 |
| Example 8 | | | | Example 4A | | | Example 4B | |
| Preparation | 1.5 | 0.5 | 13.68 | Example 5A | 17.22 | 9.79 | Example 5B | 17.18 |
| Example 9 | | | | | | | | |
| Preparation | 1 | 1 | 17.88 | Example 6A | 17.24 | 13.18 | Example 6B | 17.20 |
| Example 10 | | | | | | | | |
| Preparation | 0.5 | 1.5 | 24.67 | Example 7A | 12.27 | 20.81 | Example 7B | 17.24 |
| Example 11 | | | | | | | | |
| Preparation | 3 | 0 | 19.24 | Comparative | 17.30 | 16.13 | Comparative | 17.26 |
| Example 12 | | | | Example 5A | | | Example 5B | |
| Preparation | 2.5 | 0.5 | 22.45 | Example 8A | 17.33 | 19.73 | Example 8B | 17.28 |
| Example 13 | | | | | | | | |
| Preparation | 2 | 1 | 26.45 | Example 9A | 17.36 | 23.00 | Example 9B | 17.32 |
| Example 14 | | | | | | | | |
| Preparation | 1.5 | 1.5 | 31.48 | Example 10A | 17.40 | 27.70 | Example 10B | 17.36 |
| Example 15 | | | | | | | | |
| Preparation | 1 | 2 | 34.54 | Example 11A | 17.42 | 30.72 | Example 11B | 17.38 |
| Example 16 | | | | | | | | |
| Preparation | 0.5 | 2.5 | 38.88 | Example 12A | 17.43 | 34.18 | Example 12B | 17.40 |
| Example 17 | | | | | | | | |

An optical characteristic (TIR ratio) of a film in a preparation example and the module power generation efficiency (η) measured after the film is mounted to the backsheet of the solar cell module are as shown in Table 1, in which the T/R value is a weight ratio of TiO₂ (inorganic particle) to the fluoropolymer (solids content) after the coating layer is cured, and the B/R value is a weight ratio of the light diffusing additives to the fluoropolymer (solids content) after the coating layer is cured.

In the example of the single-sided coating layer (light-regulating layer) as shown in Table 1, the TIR value of a film in a preparation example is increased with the raise of the content of the light diffusing additives in the coating layer (Preparation Examples 2 to 4, Preparation Examples 5 to 7, Preparation Examples 8 to 11, and Preparation Examples 12 to 17), and meanwhile, when the film is mounted to the backsheet of the solar cell module, the corresponding module power generation efficiency η is also increased accordingly.

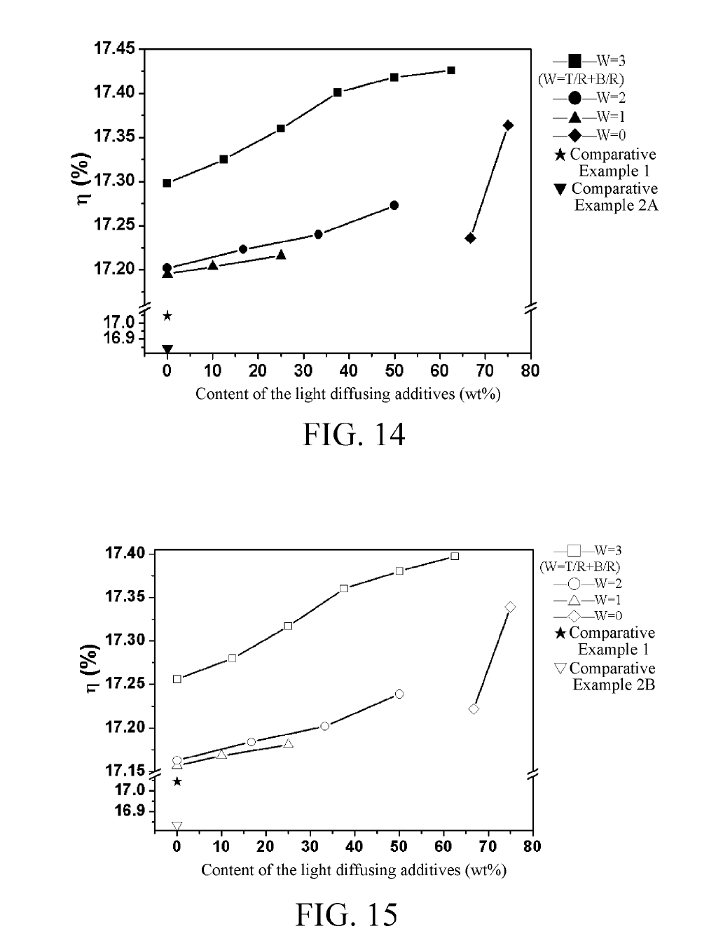

Both FIG. 14 (with the coating layer of the backsheet facing upward) and FIG. 15 (with the coating layer of the backsheet facing downward) show that, the efficiency of all the solar cell modules is increased with the raise of the content of the light diffusing additives of the film in the backsheet (the preparation examples and examples with W=(T/R+B/R)=0 to 3), and the efficiency is larger than that in Comparative Example 1 and Comparative Example 2A. The foregoing analysis results prove that, when the backsheet in the solar cell module has a light-regulating film, the power generation efficiency of the module can be significantly enhanced.

TABLE 2
Relationship between TIR and η of a
backsheet having double-sided coating layers

| | | | | | Module |
|---|---|---|---|---|---|
| | | | | | power gen- |
| | | | TIR | | eration |
| | Coating layer formula | | ratio | Cell | efficiency |
| Backsheet | T/R | B/R | (%) | module | η (%) |
| Preparation | 0 | 2 | 40.57 | Example 13 | 17.26 |
| Example 18 | | | | | |
| Preparation | 0.5 | 0.5 | 13.25 | Example 14 | 17.27 |
| Example 19 | | | | | |
| Preparation | 0.5 | 1.5 | 24.69 | Example 15 | 17.32 |
| Example 20 | | | | | |
| Preparation | 0.5 | 2.5 | 38.91 | Example 16 | 17.47 |
| Example 21 | | | | | |

Note:
The formulas of the double-sided coating layers of the films in the foregoing preparation examples are the same.

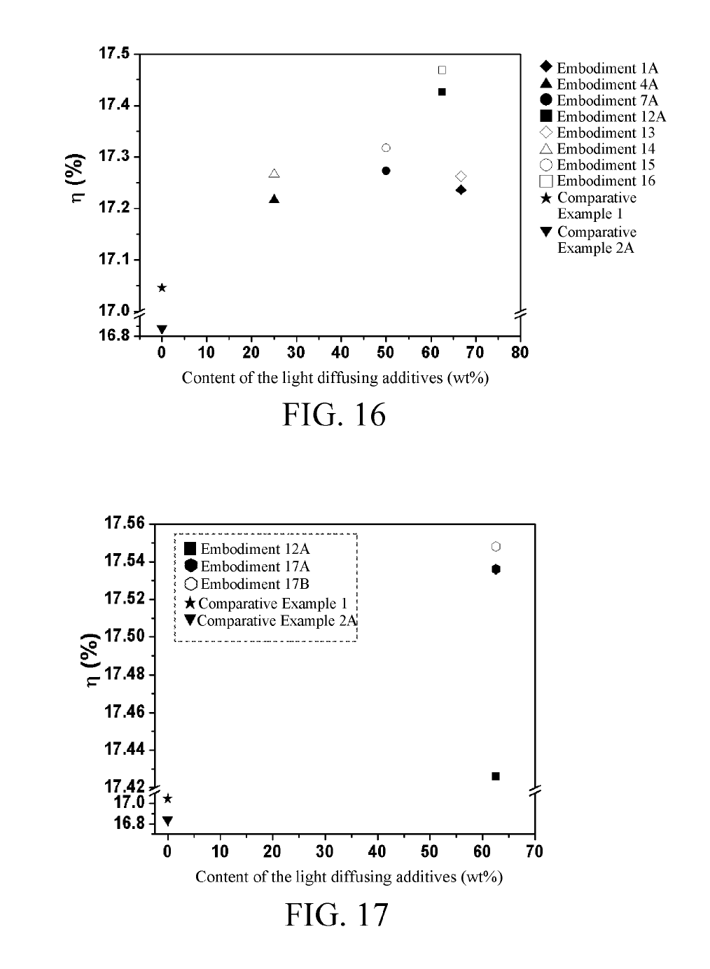

It can be clearly seen from Table 2 and FIG. 16 that, both the TIR value of the film having the double-sided coating layers (light-regulating layers) and the module power generation efficiency η obtained after the film is mounted to the backsheet of the solar cell module are also increased with the raise of the content of the light diffusing additives of the light-regulating layer, and the module power generation efficiency of the backsheet having the double-sided coating layers (Examples 13 to 16) is better than the module power generation efficiency of the backsheet having the single-sided coating layer.

TABLE 3
Relationship between TIR and η of a frontsheet having a single-sided coating layer

| | | | Coating layer of the frontsheet facing | | | | | |
|---|---|---|---|---|---|---|---|---|
| | | | upward | | | Coating layer of the frontsheet facing | | |
| | | | | | Module | downward | | |
| | Coating | | | | power | | | Module power |
| | layer | | TIR | | generation | TIR | | generation |
| | formula | | ratio | | efficiency | ratio | | efficiency |
| Frontsheet | T/R | B/R | (%) | Cell module | η (%) | (%) | Cell module | η (%) |
| Preparation | 0 | 1.8 | 15.83 | Example 17A | 17.54 | 12.67 | Example 17B | 17.55 |
| Example 22 | | | | | | | | |

It can be seen from Table 3 and FIG. 17 that, when the frontsheet of the solar cell module contains the film of the present invention (Examples 17A and 17B), the module power generation efficiency thereof is apparently greater than that of the frontsheet of the solar cell module without the film of the present invention (Example 12A), so that the film of the present invention is also applicable to the frontsheet of the solar cell module to effectively improve the power generation efficiency of the module.

We claim:

1. A film used for a solar cell module, comprising a substrate and at least one light-regulating layer, wherein the light-regulating layer comprises a fluoro resin and a plurality of light diffusing additives.

2. The film according to claim 1, wherein the film is transparent, translucent or opaque.

3. The film according to claim 1, wherein one of the surfaces of the substrate of the film is provided with the light-regulating layer.

4. The film according to claim 1, wherein both of the surfaces of the substrate of the film are provided with the light-regulating layers.

5. The film according to claim 1, wherein the plurality of light diffusing additives has a shape selected from the group consisting of spherical, rhombus-shaped, elliptical, rice grain-shaped, polygonal spherical and biconvex-shaped, and a mixture thereof.

6. The film according to claim 1, wherein the plurality of light diffusing additives has a structure selected from the group consisting of a solid structure, a hollow structure, a porous structure and a mixture thereof.

7. The film according to claim 1, wherein the material of the plurality of light diffusing additives is selected from the group consisting of glass, a metal oxide, and plastic and a mixture thereof.

8. The film according to claim 7, wherein the plurality of light diffusing additives is a plastic material selected from the group consisting of an acrylate resin, a styrene resin, a urethane resin, and a silicone resin and a mixture thereof.

9. The film according to claim 1, wherein the average particle size of the plurality of light diffusing additives is 0.5 μm to 10 μm.

10. The film according to claim 1, wherein the fluoro resin comprises a copolymer of a fluoroolefin monomer and an alkyl vinyl ether monomer.

11. The film according to claim 1, wherein the substrate is formed from the material selected from the group consisting of a polyester resin, a polyacrylate resin, a polyolefin resin, polycycloolefin resin, a polyimide resin, a polycarbonate resin, a polyurethane resin, polyvinyl chloride, triacetyl cellulose, and a polylactic acid and a combination thereof.

12. The film according to claim 1, wherein the light-regulating layer further comprises an inorganic particle selected from the group consisting of aluminum nitride, magnesium oxide, silicon nitride, boron nitride, zinc oxide, silicon dioxide, titanium dioxide, zirconium oxide, iron oxide, aluminum oxide, calcium sulfate, barium sulphate and calcium carbonate and a mixture thereof.

13. The film according to claim 1, wherein the light-regulating layer is a coating layer having an concave-convex structure.

14. A solar cell module, comprising:
a transparent frontsheet;
a backsheet; and
one or more solar cells located between the transparent frontsheet and the backsheet,
wherein at least one of the transparent frontsheet and the backsheet comprises the film according to claim 1.

15. The solar cell module according to claim 14, wherein the transparent frontsheet comprises a glass substrate, a plastic transparent substrate, the film or a combination thereof, and the backsheet comprises the film.

16. The solar cell module according to claim 15, wherein the plastic transparent substrate is formed from the material selected from the group consisting of a polyester resin, a polyacrylate resin, polyolefin resin, a polycycloolefin resin, a polyimide resin, a polycarbonate resin, a polyurethane resin, polyvinyl chloride, triacetyl cellulose, and a polylactic acid and a combination thereof.

17. The solar cell module according to claim 14, wherein the type of the solar cell is a monocrystalline silicon solar cell, a poly-silicon solar cell, an amorphous silicon solar cell, a dye-sensitized solar cell, an inorganic compound semiconductor cell, or an organic solar cell.

18. The solar cell module according to claim 17, wherein the type of the inorganic compound semiconductor cell is a III-V group compound semiconductor cell, a II-VI group compound semiconductor cell, a I-III-VI group compound semiconductor cell, or a CZTS compound semiconductor cell.
